(19) United States
(12) Patent Application Publication
(10) Pub. No.: US 2014/0071594 A1
(43) Pub. Date: Mar. 13, 2014

(54) Components Having Breakaway Installation Handles

(71) Applicants: Sawyer I. Cohen, Sunnyvale, CA (US); Jared M. Kole, San Francisco, CA (US); Andriy Pletenetskyy, Sunnyvale, CA (US); Ashutosh Y. Shukla, Santa Clara, CA (US); Michael B. Wittenberg, Sunnyvale, CA (US)

(72) Inventors: Sawyer I. Cohen, Sunnyvale, CA (US); Jared M. Kole, San Francisco, CA (US); Andriy Pletenetskyy, Sunnyvale, CA (US); Ashutosh Y. Shukla, Santa Clara, CA (US); Michael B. Wittenberg, Sunnyvale, CA (US)

(21) Appl. No.: 13/606,377

(22) Filed: Sep. 7, 2012

(51) Int. Cl. H05K 7/00; B23P 11/00; B29C 45/00

(52) U.S. Cl. 361/679.01; 264/297.2; 29/700; 29/428

(57) ABSTRACT

A component may be molded with an integral breakaway installation handle. The breakaway installation handle may be used to manipulate and maneuver the component during assembly operations and during component mounting operations. A technician may use the breakaway installation handle to mount the component to a fixture while applying adhesive, attaching a mesh, or performing other assembly operations on the component. Following assembly operations, the technician may use the breakaway installation handle to install the component in an electronic device. After installing the component in the electronic device, the technician may bend the breakaway installation handle with respect to the component until the breakaway installation handle breaks off from the component. Components having breakaway installation handles may be formed form an injection molding system in which mold cavities each receive molten plastic from a runner. Plastic that solidifies in each runner may form the breakaway installation handle for each component.

### BACKGROUND

This relates generally to electronic devices and, more particularly, to assembling, mounting, and installing components in electronic devices.

Electronic devices such as cellular telephones, computers, and other electronic devices are often provided with components such as cameras, microphones, and buttons. Bracket structures and other component mounting structures may be used in compactly and accurately mounting these components within an electronic device. As electronic devices become more compact, components and component mounting structures within electronic devices are also being manufactured with increasingly small dimensions. Conventional methods of installing miniature components within an electronic device often result in improper installation. For example, miniature components in conventional electronic devices often become damaged, improperly oriented, or poorly installed during assembly. This may result in electronic devices that exhibit component failures during use.

It would therefore be desirable to be able to provide improved ways of assembling and installing components in electronic devices.

### SUMMARY

An electronic device may have a housing in which components and component mounting structures are mounted. Components and component mounting structures may be provided with breakaway installation handles. A breakaway installation handle may be used to manipulate and maneuver a component such as a miniature component during assembly operations and during component mounting operations.

Components that may be installed using a breakaway installation handle include brackets, camera windows, camera flash windows, lenses (e.g., Fresnel lenses or other lenses), button structures, housing parts, frame structures, mounting brackets, component housings, and other mechanical or electrical parts.

A technician may use a breakaway installation handle to mount a component to a fixture during assembly operations. While the component is mounted to the fixture, assembly operations may be performed on the component. This may include, for example, applying adhesives, paints, or other coatings to the component, attaching mesh to the component, attaching other components, structures, or materials to the component, or performing other assembly operations on the component. A technician may, for example, use a breakaway installation handle to press a component against a pressure-sensitive adhesive to activate the pressure-sensitive adhesive to form a bond with the component.

Following assembly operations, a technician may use the breakaway installation handle to install the component in an electronic device by mounting the component to a component support structure in the electronic device. After mounting the component to the component support structure, the technician may bend the breakaway installation handle with respect to the component until the breakaway installation handle breaks off from the component. The breakaway installation handle may allow for precise installation of a component and may lower the risk of damaging the component during installation.

Components and breakaway installation handles may be formed using an injection molding system. A plunger may inject molten plastic into a mold that includes mold cavities and runners. Each mold cavity may receive molten plastic from an associated runner. After solidifying the molten plastic within the mold cavities and the runners, the mold may be released. The plastic that solidifies within the mold cavities may form the components, whereas the plastic that solidifies within the runners may form the breakaway installation handles.

Each component may therefore have an integral breakaway installation handle. The integral breakaway installation handle may be used to manipulate and maneuver the component during assembly operations and during component mounting operations. When the component has been assembled and/or installed, the integral breakaway installation handle may be severed from the component.

Further features of the invention, its nature and various advantages will be more apparent from the accompanying drawings and the following detailed description.

### BRIEF DESCRIPTION OF THE DRAWINGS

FIG. 1 is a perspective view of an illustrative electronic device such as a laptop computer with components that may be installed using breakaway installation handles in accordance with an embodiment of the present invention.

FIG. 2 is a perspective view of an illustrative electronic device such as a handheld electronic device with components that may be installed using breakaway installation handles in accordance with an embodiment of the present invention.

FIG. 3 is a perspective view of an illustrative electronic device such as a tablet computer with components that may be installed using breakaway installation handles in accordance with an embodiment of the present invention.

FIG. 4 is a perspective view of an illustrative component having a breakaway installation handle in accordance with an embodiment of the present invention.

FIG. 5 is a cross-sectional side view of an illustrative component having a breakaway installation handle in accordance with an embodiment of the present invention.

FIG. 6 is a diagram of illustrative steps involved in mounting a component to a component support structure using a breakaway installation handle in accordance with an embodiment of the present invention.

FIG. 7 is a perspective view of an illustrative component support structure and a component having a breakaway installation handle in accordance with an embodiment of the present invention.

FIG. 8 is a perspective view of an illustrative component having a breakaway installation handle that is held in place by an assembly fixture during assembly operations in accordance with an embodiment of the present invention.

FIG. 9 is a perspective view of an illustrative component showing how a breakaway installation handle and an assembly fixture may be used in applying adhesive to the component in accordance with an embodiment of the present invention.

FIG. 10 is diagram showing how an illustrative component having a breakaway installation handle may be formed using an injection molding system in accordance with an embodiment of the present invention.

FIG. 11 is a flow chart of illustrative steps involved in installing a component using a breakaway installation handle in accordance with an embodiment of the present invention.

FIG. 12 is a flow chart of illustrative steps involved in assembling and installing a component using a breakaway installation handle in accordance with an embodiment of the present invention.

### DETAILED DESCRIPTION

Electronic devices may be provided with components such as audio components (e.g., microphones and speakers), buttons, sensors, imaging equipment (e.g., a camera and flash), and other components. Bracket structures and other component mounting structures may be used in compactly and accurately mounting these components within an electronic device.

Components may be formed with one or more breakaway installation handles. Breakaway installation handles may be used to manipulate components during assembly and to mount components within the housing of an electronic device. A breakaway installation handle may be molded as an integral part of a component. Following installation, the breakaway installation handle may be detached from the installed component.

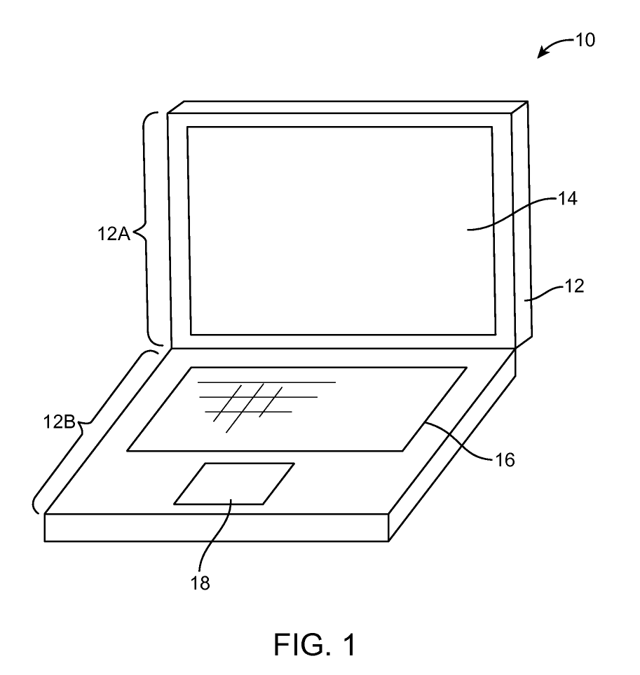

Illustrative electronic devices that may be provided with components and component mounting structures are shown in FIGS. 1, 2, and 3. FIG. 1 shows how electronic device 10 may have the shape of a laptop computer having upper housing 12A and lower housing 12B with components such as keyboard 16 and touchpad 18. Components and component mounting structures may be mounted within upper housing 12A and/or lower housing 12B.

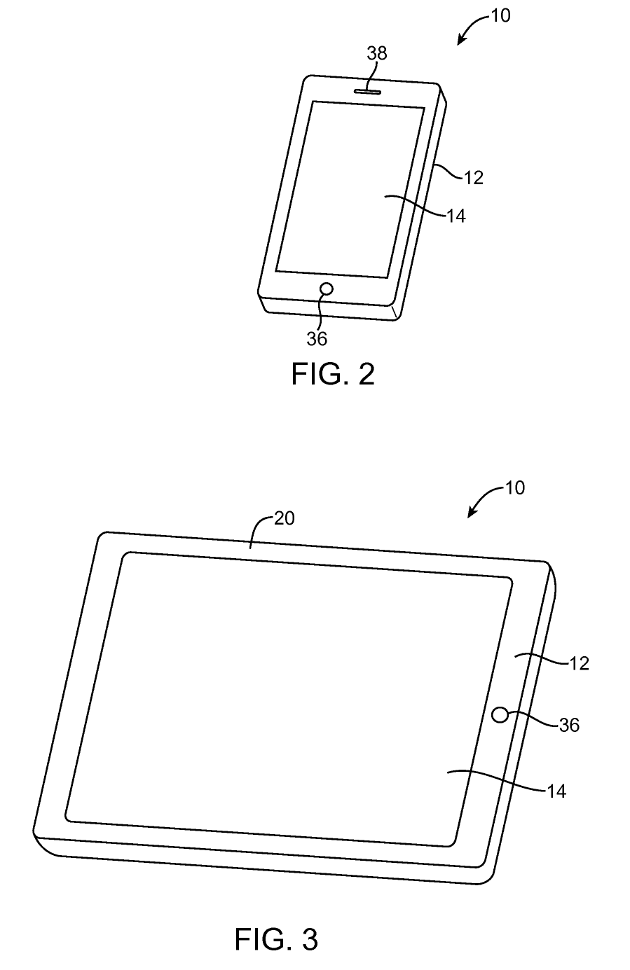

FIG. 2 shows how electronic device 10 may be a handheld device such as a cellular telephone, music player, gaming device, navigation unit, or other compact device. In this type of configuration for device 10, housing 12 may have opposing front and rear surfaces. Display 14 may mounted on a front face of housing 12. Display 14 may, if desired, have a display cover layer or other exterior layer that includes openings for components such as button 36 and speaker port 38. Components and component mounting structures may be mounted within housing 12.

FIG. 3 shows how electronic device 10 may be a tablet computer. In electronic device 10 of FIG. 3, housing 12 may have opposing planar front and rear surfaces. Display 14 may be mounted on the front surface of housing 12. As shown in FIG. 3, display 14 may have a cover layer or other external layer with an opening to accommodate button 36.

The configurations for device 10 shown in FIGS. 1, 2, and 3 are merely illustrative. In general, electronic device 10 may be a laptop computer, a computer monitor containing an embedded computer, a tablet computer, a cellular telephone, a media player, or other handheld or portable electronic device, a smaller device such as a wrist-watch device, a pendant device, a headphone or earpiece device, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment.

Device 10 may have a housing enclosure such as housing 12. Housing 12, which is sometimes referred to as a case or enclosure, may be formed of materials such as plastic, glass, ceramics, carbon-fiber composites and other composites, metal, aluminum, other materials, or a combination of these materials. Device 10 may be formed using a unibody construction in which most or all of housing 12 is formed from a single structural element (e.g., a piece of machined metal or a piece of molded plastic) or may be formed from multiple housing structures (e.g., outer housing structures that have been mounted to internal frame elements, welded standoffs, engagement structures, engagement member receiving structures, or other internal housing structures).

Device 10 may have one or more displays such as display 14. Display 14 may be a liquid crystal display, an organic light-emitting diode (OLED) display, or other suitable display. Display 14 may include display pixels formed from light-emitting diodes (LEDs), organic light-emitting diodes (OLEDs), plasma cells, electronic ink elements, liquid crystal display (LCD) components, and/or other suitable display pixel structures. Display 14 may, if desired, include capacitive touch sensor electrodes for a capacitive touch sensor array or other touch sensor structures (i.e., display 14 may be a touch screen).

Components such as audio components (e.g., microphones and speakers), buttons, sensors, imaging equipment (e.g., a camera and flash), and other components may be mounted in housing 12 of electronic device 10. An assembly of component mounting structures may be used to mount a component within a housing. For example, brackets, adhesives, coatings, screws, cosmetic meshes, and other parts or materials may form part of a camera assembly, a camera flash assembly, a speaker assembly, a microphone assembly, or other assembly in electronic device 10.

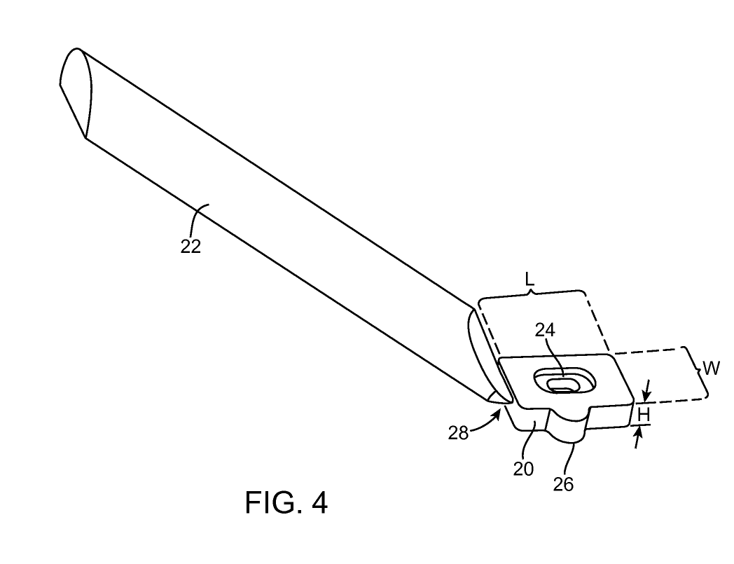

Components may be formed with breakaway installation handles to facilitate assembling and mounting the components within electronic device 10. FIG. 4 is a perspective view of an illustrative component such as component mounting structure 20 that has a breakaway installation handle such as breakaway installation handle 22. Component mounting structure 20 may, for example, be a bracket that forms part of a microphone assembly. In general, any type of component may be assembled using breakaway installation handles. For example, components such as camera windows, camera flash windows, lenses (e.g., Fresnel lenses or other lenses), button structures, housing parts, frame structures, mounting brackets, component housings, and other mechanical or electrical parts may be assembled using breakaway installation handles such as breakaway installation handle 22.

As shown in the example of FIG. 4, bracket 20 includes a recess such as recess 24 and an alignment feature such as alignment feature 26. Recess 24 may be configured to receive a microphone (as an example). Alignment feature 26 may be a protruding portion of bracket 20 that aligns and mates with a corresponding alignment feature within housing 12 of device 10.

Breakaway handle 22 may be detachably connected to bracket 20 at interface 28. As shown in FIG. 4, breakaway handle 22 includes an elongated shaft having size dimensions that are greater than the size dimensions component 20, thereby facilitating human manipulation of component 20. For example, component 22 may be a miniature component that would otherwise be difficult to install by hand (e.g., that would be difficult to install by hand without handle 22). As an illustrative example, component 22 may have a length L of about 3 mm, a width W of about 2 mm, and a height H of about 0.75 mm. By holding breakaway handle 22, a technician or robotic member may handle miniature component 22 with ease and precision. This is, however, merely illustrative. In general, component 20 may have any suitable size.

Breakaway handle 22 may be used to manipulate component 20 during assembly operations and to mount component 20 in housing 12 of device 10. For example, a technician may hold breakaway handle 22 during assembly operations and may use breakaway handle 22 to maneuver component 20 while assembling other parts to component 20, while applying coatings or adhesives to component 20, while adhering mesh to component 20 (e.g., a mesh through which sound passes to reach a microphone within recess 24 of bracket 20), or while performing other assembly operations on component 20.

Breakaway handle 22 may also be used during component mounting operations. For example, a technician may hold breakaway handle 22 while mounting component 20 (as part of an assembly or alone as a single part) in or to housing 12 (e.g., while inserting component 20 into an enclosure within housing 12 or while otherwise placing component 20 in a desired location in electronic device 10). Handle 22 may allow easy and precise installation of component 20 while ensuring that component 20 is not damaged during installation.

Handle 22 may be formed as an integral part of component 20 or may be a separate structure attached to component 20 at interface 28. In one suitable embodiment, handle 22 and component 20 may be molded as a single part (e.g., using an injection molding process or other suitable molding process). Other suitable fabrication processes that may be used to form component 20 and/or handle 22 include machining, thermoforming, or other suitable fabrication techniques.

Suitable materials that may be used to form handle 22 and component 20 include polymer (e.g., polyarylamide, polycarbonate, polycarbonate acrylonitrile butadiene styrene (PC-ABS), or other suitable polymer), glass-fiber reinforced polymer, glass, ceramic, metal, other suitable materials, or combinations of these materials.

In one suitable embodiment, handle 22 and component 20 may be formed from a high-stiffness plastic with low elongation-to-break so that minimal strain is imposed on component 20 when handle 22 is severed (e.g., broken) at interface 28. If desired, interface 28 may be half-sheared or perforated so that handle 22 is easily severed from component 20. For example, in arrangements where handle 22 is formed from metal such as sheet metal, handle 22 may be half-sheared or perforated at interface 28. This is, however, merely illustrative. Arrangements in which handle 22 and component 20 are formed from polymer may provide a clean break at interface 28 without requiring a perforated or half-sheared surface.

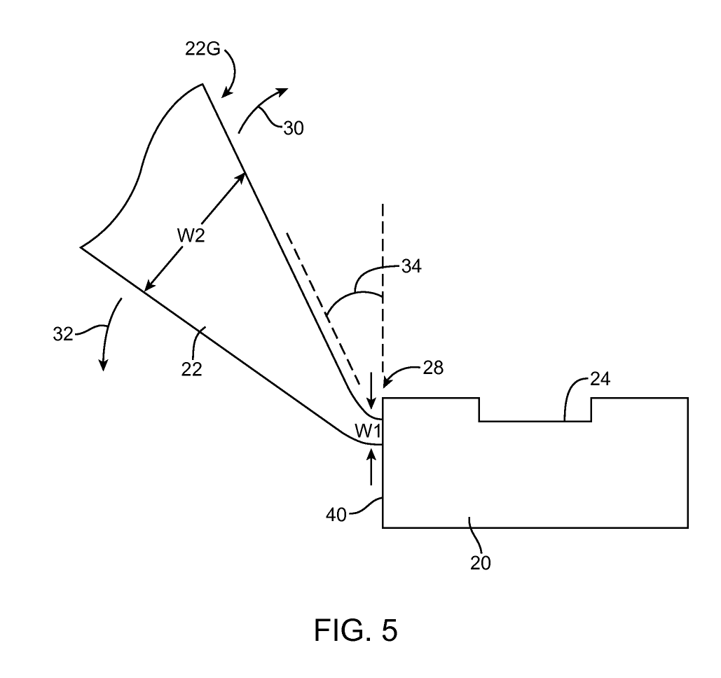

A cross-sectional side view of handle 22 and component 20 is shown in FIG. 5. As shown in FIG. 5, handle 22 may be tapered such that width W1 at interface 28 (e.g., at the break point adjacent to component 20) is less than width W2 at portions of handle 22 farther away from component 20 (e.g., at portions where a technician may grip handle 22 such as grip portions 22G). By minimizing the surface area of handle 22 that is in contact with component 20, handle 22 may be easily and cleanly broken at interface 28 by bending handle 22 in direction 30 and/or in direction 32. This may also ensure that minimal residual plastic from handle 22 remains on component 20 after handle 22 is severed.

An angle such as angle 34 may be formed between surface 40 of component 20 (e.g., surface 40 where handle 22 makes contact with component 20) and handle 22. Angle 34 may, for example, be less than 90°, less than 45°, etc. to facilitate breaking at interface 28. This is, however, merely illustrative. In general, angle 34 may be any suitable angle. For example, angle 34 may be customized depending on the type of component being installed and/or depending on the location in device 10 in which the component is being installed. Handle 22 may be bent (e.g., molded with a bend) in one or more dimensions relative to component 20 to allow for easy installation of component 20 into a recess or well in housing 12 of device 10. If desired, handle 22 may make contact with component 20 at a portion of component 20 that is not used for other functional purposes (e.g., at a portion of component 20 that is not used for adhesion, sealing, light blocking, or other purposes).

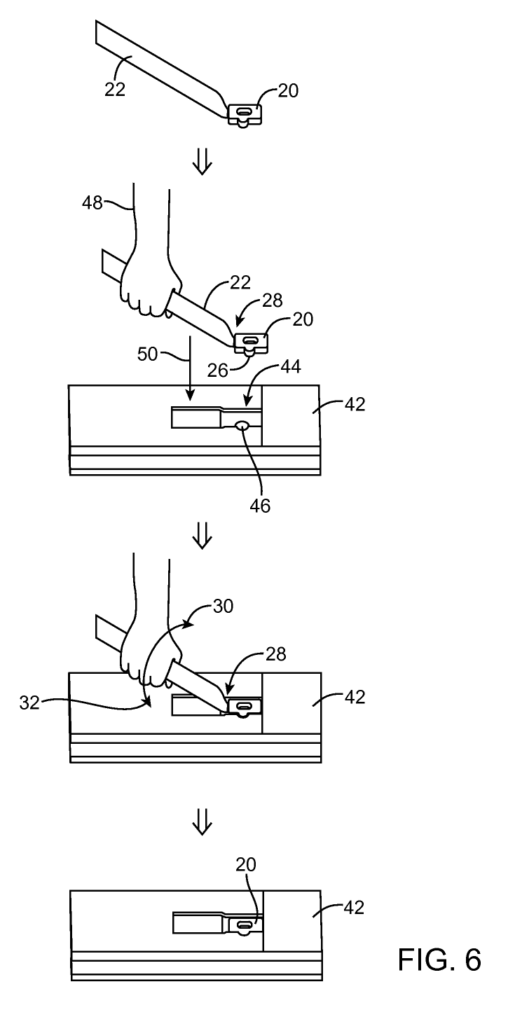

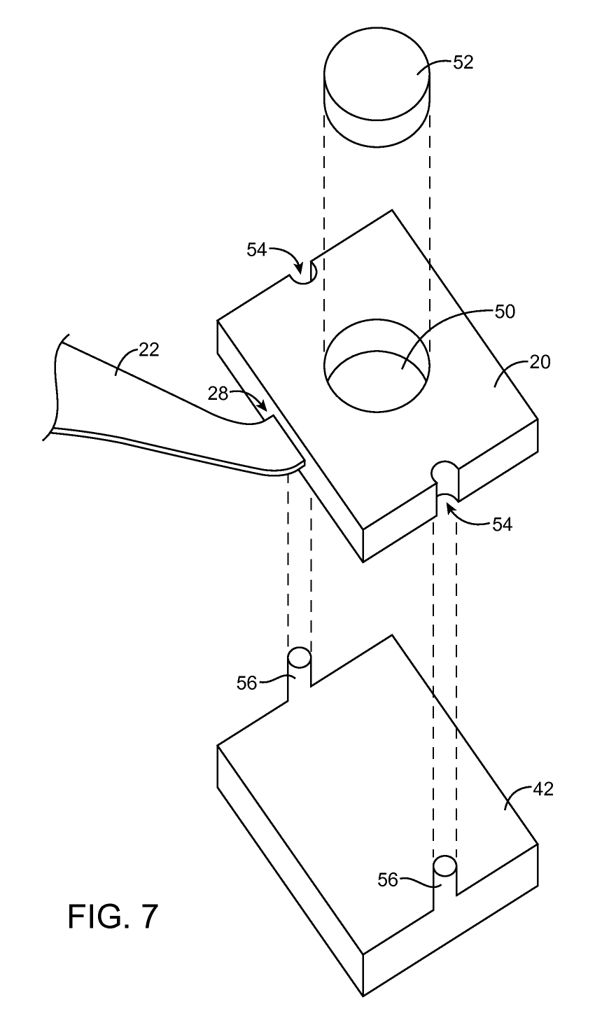

A diagram of illustrative steps involved in using handle 22 to install component 20 into a component support structure such as component support structure 42 is shown in FIG. 6. Component support structure 42 may be a part of housing 12 of device 10 or may be any other suitable component support structure within device 10.

As shown in FIG. 6, a hand such as hand 48 (e.g., a technician's hand) may hold handle 22. Component 20 may be attached to handle 22 at interface 28. Hand 48 may bring handle 22 and component 20 towards component support structure 42 (e.g., downwards in direction 50). Hand 48 may use handle 22 to mount component 20 in recess 44 of component support structure 42. Hand 48 may manipulate handle 22 to maneuver component 20 such that alignment feature 26 on component 20 aligns and mates with corresponding alignment feature 46 in structure 42 (e.g., such that protrusion 26 is received by notch 46).

When component 20 has been successfully installed in component support structure 42, handle 22 may be severed from component 20. As shown in the third illustration of FIG. 6, hand 48 may bend handle 22 in direction 30 and/or in direction 32 relative to component 20 until handle 22 breaks away from component 20 at interface 28. Handle 22 may be discarded or reused and component 20 may be securely mounted in device support structure 42 (as shown in the fourth and final illustration of FIG. 6).

FIG. 7 is a perspective view of another illustrative component 20 that may be mounted using breakaway installation handle 22. In the example of FIG. 7, component 20 forms part of a camera assembly such as a camera flash assembly. For example, opening 50 in component 20 may be a camera flash window opening through which light from a camera flash passes. A transparent flash window member such as Fresnel lens 52 may be mounted in camera flash window opening 50. Component 20 may be mounted to component support structure 42 such that alignment structures 54 of component 20 align with corresponding alignment features 56 of component support structure 42 (e.g., such that notches 54 of component 20 receive and mate with protrusions 56 of structure 42).

If desired, component support structure 42 may form part of housing 12 of device 10 or may be any other suitable component support structure within device 10. Lens 52 may, for example, be mounted directly within a camera flash window opening in housing 12 of device 10. The example of FIG. 7 in which lens 52 is mounted within camera flash window opening of lens receiving structure 50 is merely illustrative.

A technician may mount lens 52 within opening 50 before component 20 is mounted to component support structure 42 or, if desired, a technician may mount lens 52 within opening 50 after component 20 is mounted to component support structure 42. The technician may hold handle 22 to maneuver and properly install component 20 on structure 42. When component 20 is properly installed, the technician may break handle 22 at interface 28 to leave the desired part (component 22) successfully installed in structure 42.

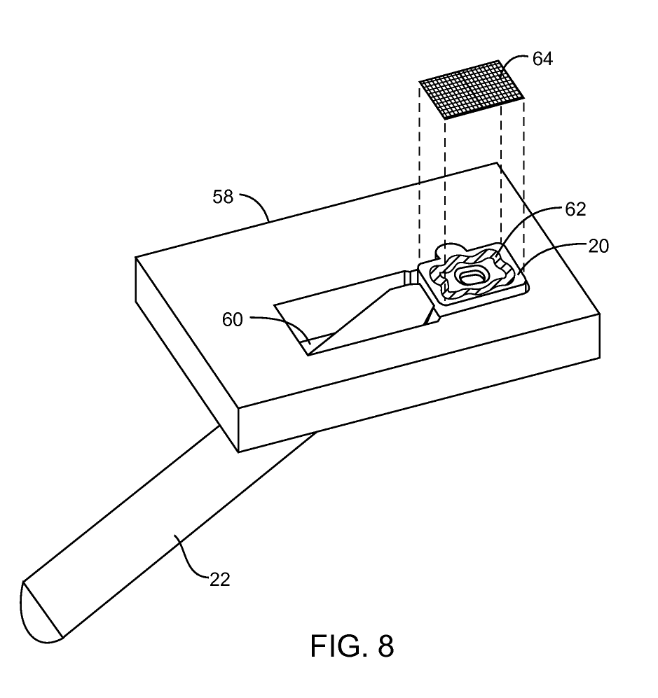

In addition to facilitating component mounting operations, breakaway handle 22 may also be used to manipulate component 20 during assembly operations. FIG. 8 is a perspective view of an illustrative configuration in which handle 22 is used to manipulate component 20 during assembly operations. As shown in FIG. 8, handle 22 may be used to mount component 20 to a fixture such as assembly fixture 58. Component 20 may be received by an opening such as opening 60 in fixture 58.

Fixture 58 may be used to hold component 20 in place while assembly operations are performed on component 20. For example, fixture 58 may hold component 20 in place while other materials, structures, and/or components are assembled to component 20. As shown in FIG. 8, a coating such as coating 62 may be applied to the surface of component 20 while component 20 is mounted to assembly fixture 58. Coating 62 may be adhesive (e.g., liquid adhesive, light-cured adhesive, pressure-sensitive adhesive or other suitable adhesive), paint, ink, sealant, or other suitable material.

While handle 22 and fixture 58 are used to hold component 20 in place, other parts or materials may be assembled to component 20. For example, in arrangements where component 20 is a microphone bracket, coating 62 may be an adhesive that is used in attaching mesh such as mesh 64 to component 20. Mesh 64 may have an array of openings that allow sound to reach a microphone in device 10 while providing a cover for a microphone port in housing 12 of device 10. Mesh 64 may be formed from metal, plastic, other materials, or multiple mesh layers. This is, however, merely illustrative. In general, any suitable assembly operation may be performed on component 20 while component 20 is mounted to fixture 58. For example, other materials, structures, or components may be assembled to component 20 while component 20 is held in place by fixture 58 (e.g., other/additional coatings, additional meshes, alignment structures, engagement members, brackets, lenses, button structures or other component parts, etc.) The examples in which adhesive 62 is used to attach mesh 64 to microphone bracket 20 is merely illustrative.

Suitable materials that may be used to form fixture 58 include polymer (e.g., polyarylamide, polycarbonate, polycarbonate acrylonitrile butadiene styrene (PC-ABS), or other suitable polymer), glass-fiber reinforced polymer, glass, ceramic, metal, other suitable materials, or combinations of these materials. If desired, fixture 58 may be molded (e.g., using an injection molding process or other suitable molding process).

The example of FIG. 8 in which fixture 58 has a rectangular shape with rectangular opening 60 that receives component 20 is merely illustrative. In general, fixture 58 may have any suitable shape and may have any suitable component receiving features. The shape, size, and structure of fixture 58 may be customized depending on the type of component being assembled and/or depending on the type of assembly operation being performed.

Following assembly operations, a technician may use handle 22 to remove the assembly (e.g., the assembly that includes component 20, adhesive 62, and mesh 64) from fixture 58 and to install the assembly into device 10. Following installation, the technician may break handle 22 at interface 28, thereby leaving component 20, adhesive 62, and mesh 64 fully assembled and securely mounted in device 10.

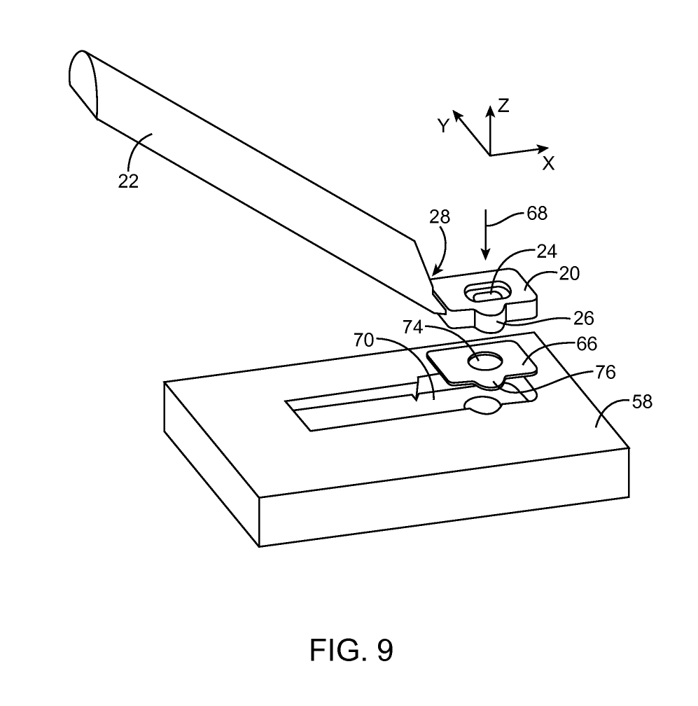

FIG. 9 is a perspective view of another illustrative configuration in which handle 22 is used to manipulate component 20 during assembly operations. In the example of FIG. 9, a fixture such as assembly fixture 58 is used in applying a layer of material such as adhesive 66 to component 20. Adhesive 66 may, for example, be a pressure sensitive adhesive that forms a bond with component 20 when adhesive 66 is pressed against component 20. Adhesive 66 may have a footprint in the X-Y plane that matches that of component 20. For example, adhesive 66 may have an opening such as opening 74 and a protruding portion such as protruding portion 76 that align respectively with opening 24 and alignment feature 26 of component 20.

Breakaway handle 22 and fixture 58 may be used to help activate adhesive 66 to form a bond with component 20. For example, adhesive 66 may be received within recess 70 of fixture 58. Using handle 22 to maneuver component 20, a technician may press component 20 against adhesive 66 (e.g., in direction 68). Because adhesive 66 is sandwiched between fixture 58 and component 20, the downward pressure provided by pressing component 20 in direction 68 (using handle 22) may activate adhesive 66 to form an adhesive bond with component 20.

Following assembly operations, a technician may use handle 22 to remove the assembly (e.g., the assembly that includes component 20 and adhesive 66) from fixture 58 and to install the assembly into device 10. Following installation, the technician may break handle 22 at interface 28, thereby leaving component 20 and adhesive 66 fully assembled and securely mounted in device 10.

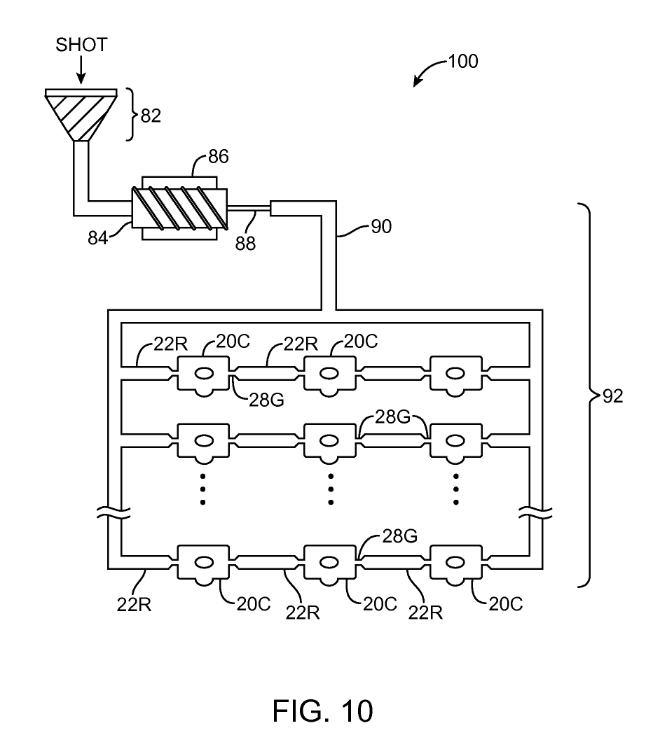

FIG. 10 is a diagram of an illustrative injection molding system showing how components 20 having breakaway installation handles 22 may be formed. As shown in FIG. 10, injection molding system 100 may include a mold such as mold 92. Mold 92 may include a plurality of mold cavities such as mold cavities 20C. Each mold cavity 20C may each have the negative shape of component 20 (FIG. 4) such that, when filled with plastic, the resulting part has the shape of component 20. Mold cavities 20C may be interconnected by mold runners such as mold runners 22R. Each mold runner 22R may have the negative shape of breakaway handle 22 (FIG. 4) such that, when filled with plastic, the resulting part has the shape of breakaway handle 22. A gate such as gate 28G may be interposed between each runner 22R and mold cavity 20C. Each gate 28G may have the negative shape of interface (FIG. 4) such that, when filled with plastic, the resulting part has the shape of interface 28 (e.g., such that the surface area of handle 22 in contact with component 20 is minimized).

As shown in FIG. 10, a shot of pelletized thermoplastic material (e.g., thermoplastic granules or “resin”) may be added to a hopper such as hopper 82. The material may be gravity fed into a screw-type plunger such as plunger 84 (or an injection ram) that is heated by heating unit 86. The heat generated by heating unit 86 and the rotation of the screw in plunger 84 may result in elevated temperatures and a shearing action on the thermoplastic pellets that causes the pellets to melt into molten plastic. Screw rotation in plunger 84 may push the molten plastic towards nozzle 88. A sprue such as sprue 90 may have an opening through which nozzle 88 may be inserted. Plunger 84 may inject the molten plastic into sprue 90, which may in turn redirect the molten plastic into runners 22R, gates 28G, and mold cavities 20C.

When mold 92 has been completely filled, the molten plastic may be cooled. The plastic that solidifies within runners 22R, gates 28G and mold cavities 20C may respectively form breakaway handles 22, interfaces 28 (e.g., the break point of handles 22), and components 20. At the completion of the cooling cycle, mold 92 may be released and adjacent assemblies may be severed from each other. For example, the hardened plastic that is released from mold 92 may be separated (severed) into individual assemblies which each include component 20 and breakaway installation handle 22 joined by interface 28.

With this type of configuration, the plastic that hardens within runners 22R of injection molding system 100 may be used as breakaway handles 22 for components 20. This may reduce wasted plastic in an injection molding system. However, the fabrication process described in connection with FIG. 10 is merely illustrative. If desired, component 20 and breakaway handle 22 may be formed from a specialized mold having a designated mold cavity to form handle 22. As additional examples, component 20 and breakaway handle 22 may be molded separately and subsequently attached together or component 20 and breakaway handle 22 may be formed using an overmolding process (e.g., where one part is molded over the other). The example of FIG. 10 is merely illustrative.

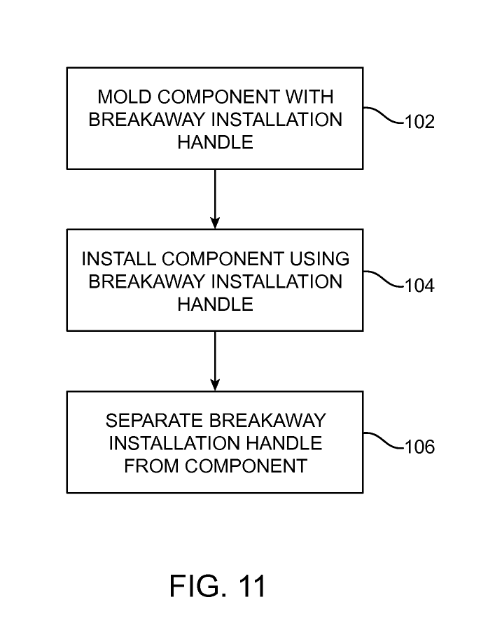

FIG. 11 is a flow chart of illustrative steps involved in installing a component such as component 20 into electronic device 10 using a breakaway installation handle such as breakaway installation handle 22 (FIG. 4).

At step 102, a component may be molded having a breakaway installation handle. This may include, for example, using an injection molding system such as injection molding system 100 of FIG. 10 to mold a plurality of components each having a breakaway installation handle. Components that may be installed using a breakaway installation handle include brackets, camera windows, camera flash windows, lenses (e.g., Fresnel lenses or other lenses), button structures, housing parts, frame structures, mounting brackets, component housings, and other mechanical or electrical parts.

At step 104, a technician or robotic member may install the component into an electronic device such as electronic device 10 using the breakaway installation handle that is detachably connected to the component. The breakaway installation handle may allow the technician or robotic member to manipulate and maneuver the component into an enclosure within the electronic device or to otherwise mount the component in a desired location in the electronic device. The breakaway installation handle may allow for easy and precise installation of the component while ensuring that the component is not damaged during installation.

At step 106, the technician or robotic member may separate the breakaway installation handle from the component. This may include, for example, bending the handle with respect to the component such that it snaps off at the handle-component interface (e.g., interface 28 of FIG. 4). After severing the breakaway installation handle from the component, the component may remain successfully installed in the electronic device and the breakaway installation handle may be discarded or reused.

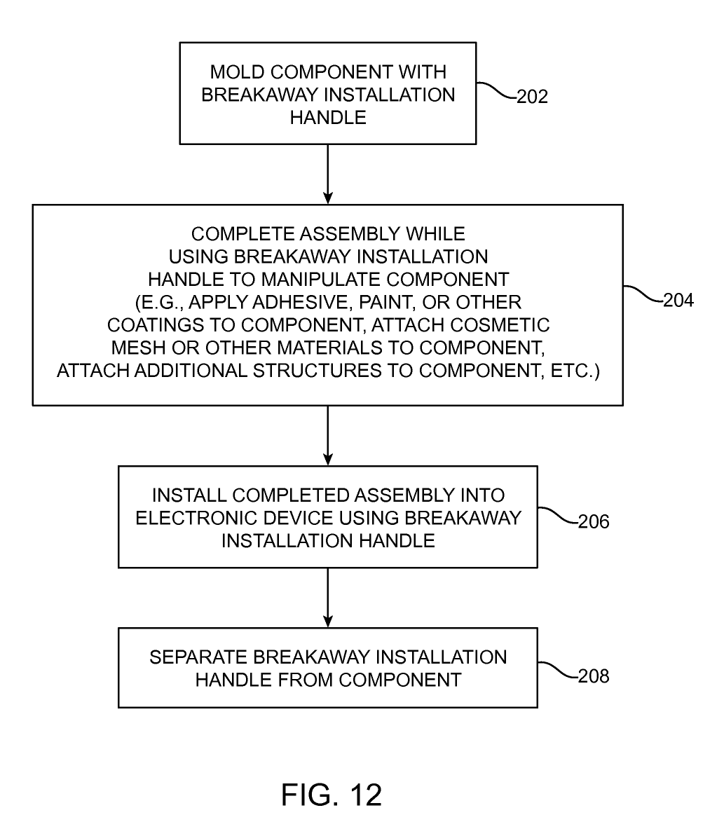

FIG. 12 is a flow chart of illustrative steps involved in assembling and installing a component such as component 20 using a breakaway installation handle such as breakaway installation handle 22 (FIG. 4).

At step 202, a component may be molded having a breakaway installation handle. This may include, for example, using an injection molding system such as injection molding system 100 of FIG. 10 to mold a plurality of components each having a breakaway installation handle. Components that may be installed using a breakaway installation handle include brackets, camera windows, camera flash windows, lenses (e.g., Fresnel lenses or other lenses), button structures, housing parts, frame structures, mounting brackets, component housings, and other mechanical or electrical parts.

At step 204, the breakaway handle may be used to manipulate and maneuver the component while assembly operations are performed on the component to form a completed assembly. This may include, for example, applying adhesives, paints, or other coatings to the component (e.g., coating 62 of FIG. 8 or adhesive 66 of FIG. 9), attaching mesh to the component (e.g., a mesh such as mesh 64 of FIG. 8), attaching other components, structures, or materials to the component (e.g., other/additional coatings, additional meshes, alignment structures, engagement members, brackets, lenses, button structures or other component parts, etc.), or performing other assembly operations on the component while the component is attached to the breakaway installation handle. If desired, a fixture such as assembly fixture 58 of FIGS. 8 and 9 may be used to hold the component in place while assembly operations are performed on the component.

At step 206, a technician or robotic member may install the completed assembly into an electronic device such as electronic device 10 using the breakaway installation handle that is detachably connected to the component. The breakaway installation handle may allow the technician or robotic member to manipulate and maneuver the assembly into an enclosure within the electronic device or to otherwise mount the assembly in a desired location in the electronic device. The breakaway installation handle may allow for easy and precise installation of the assembly while ensuring that the assembly is not damaged during installation.

At step 208, the technician or robotic member may separate the breakaway installation handle from the component. This may include, for example, bending the handle with respect to the component such that it snaps off at the handle-component interface (e.g., interface 28 of FIG. 4). After severing the breakaway installation handle from the component, the assembly may remain successfully installed in the electronic device and the breakaway installation handle may be discarded or reused.

The foregoing is merely illustrative of the principles of this invention and various modifications can be made by those skilled in the art without departing from the scope and spirit of the invention.

What is claimed is:

1. Apparatus, comprising:
a molded component configured to be installed in a component support structure; and
a breakaway installation handle integral with the molded component, wherein the breakaway installation handle is configured to break at an interface that joins the breakaway installation handle with the molded component after the molded component has been installed in the component support structure.

2. The apparatus defined in claim 1 wherein the molded component is a bracket.

3. The apparatus defined in claim 1 wherein the molded component forms part of a camera assembly.

4. The apparatus defined in claim 1 wherein the molded component and the breakaway installation handle comprise glass-fiber reinforced polymer.

5. The apparatus defined in claim 1 wherein the breakaway installation handle comprises an elongated shaft that is larger in size than the molded component.

6. The apparatus defined in claim 1 wherein the breakaway installation handle comprises a break point adjacent to the molded component and a grip portion that is farther from the molded component than the break point, wherein the breakaway installation handle has a first width at the break point and a second width at the grip portion, and wherein the first width is less than the second width.

7. The apparatus defined in claim 1 wherein the component support structure comprises an electronic device housing.

8. The apparatus defined in claim 1 wherein the component support structure comprises an alignment feature and wherein the molded component comprises a corresponding alignment feature configured to mate with the alignment feature of the component support structure.

9. A method for installing a component having a breakaway installation handle, comprising:
using the breakaway installation handle, mounting the component to a component support structure to install the component in the component support structure; and
after mounting the component to the component support structure, separating the breakaway installation handle from the component.

10. The method defined in claim 9 wherein the breakaway installation handle comprises an elongated shaft and wherein separating the breakaway installation handle form the component comprises bending the elongated shaft with respect to the component until it breaks away from the component.

11. The method defined in claim 9 further comprising:
with an injection molding system, injection molding the component and the breakaway installation handle as an integral structure.

12. The method defined in claim 9 wherein the component support structure forms part of an electronic device and wherein mounting the component to the component support structure comprises installing the component in the electronic device, the method further comprising:
using the breakaway installation handle, mounting the component to an assembly fixture prior to installing the component in the electronic device; and
while the component is mounted to the assembly fixture, applying adhesive to the component.

13. The method defined in claim 9 wherein the component support structure forms part of an electronic device and wherein mounting the component to the component support structure comprises installing the component in the electronic device, the method further comprising:
using the breakaway installation handle, mounting the component to an assembly fixture prior to installing the component in the electronic device; and
while the component is mounted to the assembly fixture, attaching a mesh to the component.

14. The method defined in claim 9 wherein the component support structure forms part of an electronic device and wherein mounting the component to the component support structure comprises installing the component in the electronic device, the method further comprising:
using the breakaway installation handle, pressing the component against a pressure-sensitive adhesive to activate the pressure-sensitive adhesive to form a bond with the component.

15. A method, comprising:
with a plunger, injecting molten plastic into a mold, wherein the mold includes a plurality of mold cavities and a plurality of runners and wherein each mold cavity in the plurality of mold cavities receives the molten plastic via an associated runner in the plurality of runners;
solidifying the molten plastic within each mold cavity in the plurality of mold cavities and the molten plastic within each runner in the plurality of runners; and
releasing the mold to obtain a plurality of components each having an integral breakaway handle, wherein each breakaway handle comprises plastic that solidified within a respective one of the runners in the plurality of runners.

16. The method defined in claim 15 further comprising:
installing at least one component in the plurality of components into an electronic device using the at least one component's integral breakaway handle.

17. The method defined in claim 16 further comprising:
when the at least one component has been installed in the electronic device, severing the at least one component's integral breakaway handle from the at least one component.

18. The method defined in claim 17 wherein the at least one component's integral breakaway handle comprises an elongated shaft and wherein severing the at least one component's integral breakaway handle from the at least one component comprises bending the elongated shaft with respect to the at least one component until it breaks away from the at least one component.

19. The method defined in claim 15 further comprising:
applying adhesive to at least one component in the plurality of components while holding the at least one component's integral breakaway handle.

20. The method defined in claim 19 further comprising:
after applying adhesive to the at least one component, installing the at least one component in an electronic device using the at least one component's integral breakaway handle; and
severing the at least one component's integral breakaway handle from the at least one component after installing the at least one component in the electronic device.
